(19) United States
(12) Patent Application Publication
(10) Pub. No.: US 2008/0003728 A1
(43) Pub. Date: Jan. 3, 2008

(54) THIN FILM TRANSISTOR ARRAY PANEL AND METHOD OF MANUFACTURING THE SAME

(75) Inventors: Tae-Hyung HWANG, Seoul (KR); Hyung-Il JEON, Incheon-si (KR); Nam-Seok ROH, Seongnam-si (KR); Sang-Il KIM, Yongin-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD, Suwon-si (KR)

(21) Appl. No.: 11/619,407

(22) Filed: Jan. 3, 2007

(30) Foreign Application Priority Data
Jun. 28, 2006 (KR) 10-2006-0058577

(51) Int. Cl. H01L 21/84

(52) U.S. Cl. 438/151

(57) ABSTRACT

A thin film transistor array panel and a method of manufacturing the same include: forming a gate electrode on an insulating substrate; sequentially forming a gate insulating layer; a semiconductor material layer and an ohmic contact material layer on the gate electrode; forming a first semiconductor layer pattern and a first ohmic contact pattern for covering the gate electrode and a surrounding area of the gate electrode by patterning the semiconductor material layer and the ohmic contact material layer; forming a conductive film on the gate insulating layer and the first ohmic contact pattern; forming a conductive film pattern on a partial area of the first ohmic contact pattern and a data line on the gate insulating layer by patterning the conductive film; forming a second ohmic contact pattern and a second semiconductor layer pattern by sequentially etching the first ohmic contact pattern and the first semiconductor layer pattern exposed by deviating from the conductive film pattern; forming a source electrode and a drain electrode separated from each other by patterning the conductive film pattern; forming an ohmic contact by etching the second ohmic contact pattern exposed between the separated source electrode and drain electrode; and forming a pixel electrode connected to the drain electrode. Therefore, even if an insulating substrate expands due to heat, erroneous alignment is not generated between a projection of the semiconductor layer and the source electrode and the drain electrode, thereby improving manufacturing efficiency and performance of a thin film transistor array panel.

This application claims priority to Korean Patent Application No. 10-2006-0058577, filed on Jun. 28, 2006, and all the benefits accruing therefrom under 35 U.S.C. § 119, the contents of which in its entirety are herein incorporated by reference.

### BACKGROUND OF THE INVENTION

(a) Field of the Invention

The present invention relates to a thin film transistor array panel used in a display device, and a method of manufacturing the same.

(b) Description of the Related Art

Recently, instead of an existing cathode-ray tube (“CRT”), a flat panel display, such as a liquid crystal display (“LCD”), an organic light emitting diode (“OLED”) and an electrophoretic display, has been widely used.

The liquid crystal display, the OLED and the electrophoretic display include a thin film transistor array panel in which a plurality of pixel electrodes and a plurality of thin film transistors are arranged in a matrix shape. Each of the plurality of thin film transistors are connected one by one to a respective pixel electrode.

The thin film transistor array panel has a stacked structure of a plurality of thin films which are patterned on an insulating substrate. In order to form the stacked structure, a process of patterning a thin film through depositing a thin film on the insulating substrate and a photolithography process using an exposure mask should be repeatedly performed. There are various methods of manufacturing a thin film transistor array panel, but a five-mask process using five exposure masks is generally used.

The five mask process is a process of using a total of five exposure masks in manufacturing a thin film transistor array panel. The five exposure masks for each case include (1) forming a gate line on an insulating substrate, (2) forming an intrinsic semiconductor stripe layer including a plurality of projections and a plurality of impurity semiconductor patterns on a gate insulating layer, (3) forming a data line and a drain electrode including a source electrode, (4) forming a passivation layer having a contact hole for exposing a drain electrode, and (5) forming a pixel electrode connected to the drain electrode through the contact hole.

However, in manufacturing a thin film transistor array panel, a heat treatment process is required for deposition of a thin film, improvement of etching efficiency, drying, baking, and so on.

An insulating substrate of a thin film transistor array panel expands due to heat in the heat treatment process during manufacturing. Accordingly, a projection of an intrinsic semiconductor stripe which is formed on the insulating substrate moves from an original position due to the heat expansion. Therefore, even if a third mask, which is used for forming a source electrode and a drain electrode, is aligned in a proper position by patterning a conductive film formed on the projection of the intrinsic semiconductor stripe, an error is generated when the formed source electrode and drain electrode align with the projection of the lower semiconductor stripe. This causes a manufacturing defect of a thin film transistor, which is a switching element, so that manufacturing efficiency and performance of the thin film transistor array panel are deteriorated.

Such a problem is more serious when gradually increasing a size of an insulating substrate so as to increase an image or enhance product production efficiency and when using a plastic having a large thermal expansion coefficient as a material for the insulating substrate.

### BRIEF SUMMARY OF THE INVENTION

The present invention has been made in an effort to provide a thin film transistor array panel and a method of manufacturing the same having advantages of having excellent manufacturing efficiency and performance.

An exemplary embodiment of the present invention provides a thin film transistor array panel including: a gate electrode formed on an insulating substrate; a gate insulating layer, a semiconductor layer pattern and an ohmic contact sequentially formed on the gate electrode; a source electrode and a drain electrode formed on the ohmic contact; a data line connected to the source electrode; and a pixel electrode connected to the drain electrode, wherein the semiconductor layer pattern includes a part having substantially a same layout as that of the source electrode and the drain electrode and wherein at least a portion of the data line is formed directly on the gate insulating layer.

The insulating substrate may be flexible.

The insulating substrate may be made of plastic.

A remaining part except a channel part in the semiconductor layer pattern may include a part having substantially a same layout as that of the source electrode and the drain electrode.

The ohmic contact may include a part having substantially a same layout as that of the source electrode and the drain electrode.

Another exemplary embodiment of the present invention provides a method of manufacturing a thin film transistor array panel. The method includes: forming a gate electrode on an insulating substrate; sequentially forming a gate insulating layer, a semiconductor material layer and an ohmic contact material layer on the gate electrode; forming a first semiconductor layer pattern and a first ohmic contact pattern for covering the gate electrode and a surrounding area of the gate electrode by patterning the semiconductor material layer and the ohmic contact material layer; forming a conductive film on the gate insulating layer and the first ohmic contact pattern; forming a conductive film pattern on a partial area of the first ohmic contact pattern and and a data line on the gate insulating layer by patterning the conductive film; forming a second ohmic contact pattern and a second semiconductor layer pattern by sequentially etching the first ohmic contact pattern and the first semiconductor layer pattern exposed by deviating from the conductive film pattern; forming a source electrode and a drain electrode separated from each other by patterning the conductive film pattern; forming an ohmic contact by etching the second ohmic contact pattern exposed between the separated source electrode and drain electrode; and forming a pixel electrode connected to the drain electrode.

The forming of the conductive film pattern may include forming a photoresist on the conductive film; exposing the photoresist using an exposure mask including a first part consisting of only a transparent substrate, a second part consisting of a non-transparent film having a plurality of slit shapes on the transparent substrate, and a third part consisting of a non-transparent film formed in a predetermined thickness on the transparent substrate; forming a photoresist pattern in which a fourth part of the developed photoresist corresponding to the second part by developing the exposed photoresist has a smaller thickness than a fifth part of the developed photoresist corresponding to the third part; and etching the conductive film using the photoresist pattern as an etching mask.

In the forming of the second ohmic contact pattern and the second semiconductor layer, the fifth part of the photoresist pattern may be removed through etching.

The forming of the source electrode and the drain electrode may include etching the conductive film pattern using the photoresist pattern in which the fifth part is removed as an etching mask.

The forming of the ohmic contact may include etching the second ohmic contact pattern using the photoresist pattern in which the fifth part is removed as an etching mask.

The insulating substrate may be flexible.

The insulating substrate may be made of plastic.

In the forming of the ohmic contact, the ohmic contact may include a part having substantially a same layout as that of the source electrode and the drain electrode.

In the forming of the second semiconductor layer pattern, the second semiconductor layer pattern may include a part having substantially a same layout as that of the source electrode and the drain electrode.

In the forming of the second semiconductor layer pattern, the remaining part except for a channel part in the second semiconductor layer pattern may have substantially a same layout as that of the source electrode and the drain electrode.

### BRIEF DESCRIPTION OF THE DRAWINGS

The present invention will become more apparent by describing exemplary embodiments thereof in more detail with reference to the accompanying drawings, in which:

FIG. 1 is a plan view layout illustrating a structure of a thin film transistor array panel for a liquid crystal display according to an exemplary embodiment of the present invention;

FIG. 2 is a cross-sectional view of the thin film transistor array panel taken along line II-II of FIG. 1;

FIGS. 3A, 4A, 5A, 6A, 7A, and 8A are plan view layouts sequentially illustrating the thin film transistor array panel in an intermediate step of a method of manufacturing the thin film transistor array panel shown in FIGS. 1 and 2 according to an exemplary embodiment of the present invention.

FIG. 3B is a cross-sectional view of the thin film transistor array panel taken along line IIIb-IIIb of FIG. 3A;

FIG. 4B is a cross-sectional view of the thin film transistor array panel taken along line IVb-IVb of FIG. 4A;

FIG. 5B is a cross-sectional view of the thin film transistor array panel taken along line Vb-Vb of FIG. 5A;

FIG. 6B is a cross-sectional view of the thin film transistor array panel taken along line VIb-VIb of FIG. 6A;

FIG. 7B is a cross-sectional view of the thin film transistor array panel taken along line VIIb-VIIb of FIG. 7A; and

FIG. 8B is a cross-sectional view of the thin film transistor array panel taken along line VIIIb-VIIIb of FIG. 8A.

### DETAILED DESCRIPTION OF THE INVENTION

The present invention now will be described more fully hereinafter with reference to the accompanying drawings, in which exemplary embodiments of the present invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. Further, it will be understood that when a first element is referred to as being “on” a second element, the first element may be above or below the second element. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

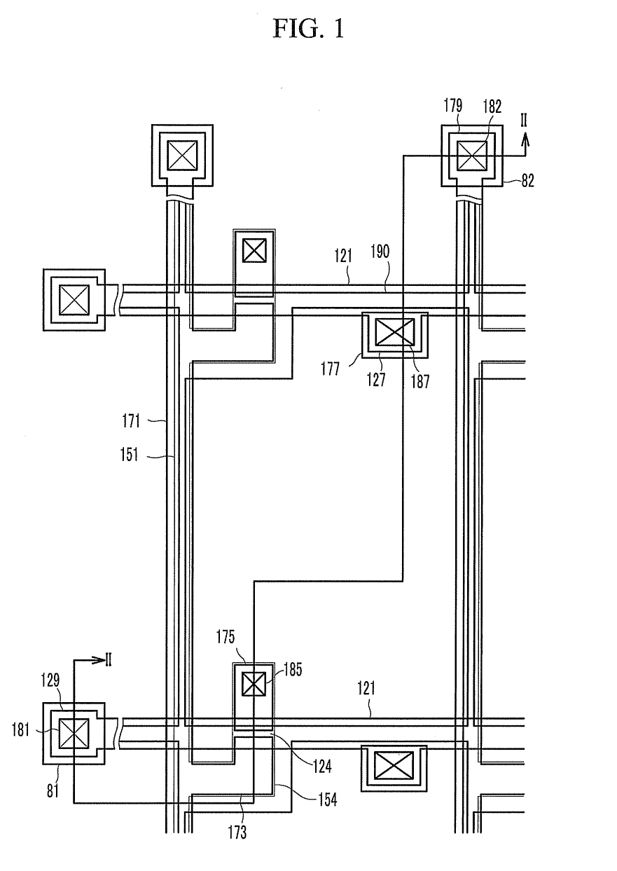

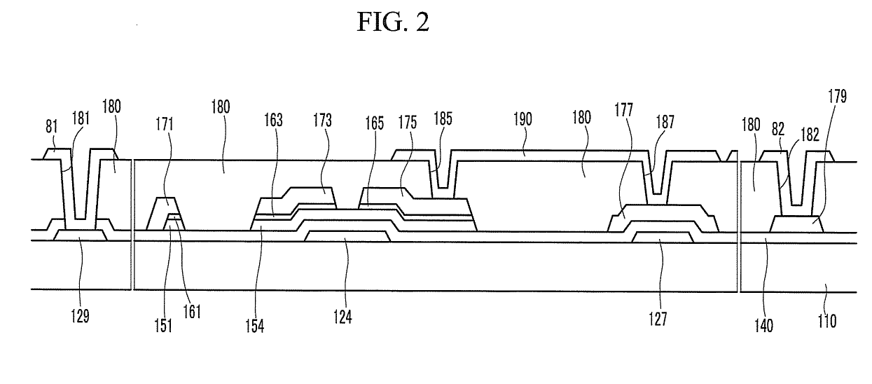

The present invention will be described more fully hereinafter with reference to the accompanying drawings, in which exemplary embodiments of the present invention are shown. As those skilled in the art would realize, the described exemplary embodiments may be modified in various different ways, all without departing from the spirit or scope of the present invention. Now, a structure of a thin film transistor array panel according to an exemplary embodiment of the present invention will be described in more detail with reference to FIGS. 1 and 2.

FIG. 1 is a plan view layout illustrating a structure of a thin film transistor array panel for a liquid crystal display according to an exemplary embodiment of the present invention. FIG. 2 is a cross-sectional view of the thin film transistor array panel taken along line II-II of FIG. 1.

The thin film transistor array panel shown in FIGS. 1 and 2 is a thin film transistor array panel for a liquid crystal display, and may be a thin film transistor array panel for an OLED or an electrophoretic display, for example, but is not limited thereto.

A plurality of gate lines 121 for transferring a gate signal is formed on an insulating substrate 110 made of flexible plastic, transparent glass, etc.

The gate lines 121 extend in substantially a horizontal direction. Each gate line 121 includes a plurality of gate electrodes 124, a plurality of expansions 127 which protrude downwardly, and a wide end part 129 for connecting to other layers or an external driver circuit (not shown).

The gate lines 121 may be made of an aluminum metal such as aluminum (Al) or an aluminum alloy, a silver metal such as silver (Ag) or a silver alloy, a copper metal such as copper (Cu) or a copper alloy, a molybdenum metal such as molybdenum (Mo) or a molybdenum alloy, chrome (Cr), tantalum (Ta), titanium (Ti), for example, but is not limited thereto. However, the gate lines 121 may have a multilayer structure including two conductive films (not shown) having different physical properties. One conductive film among them is made of a metal having low resistivity, for example an aluminum metal, a silver metal, a copper metal, and so on in order to reduce a signal delay or a voltage drop. Alternatively, the other conductive film is made of materials such as molybdenum metals, chromium, tantalum, titanium, and so on which have excellent physical, chemical and electrical contact characteristics with other materials, particularly indium tin oxide (“ITO”) and indium zinc oxide (“IZO”). A good example of such a combination may include a lower chromium layer and an upper aluminum (alloy) layer, or a lower aluminum (alloy) layer and an upper molybdenum (alloy) layer, but is not limited thereto. However, the gate lines 121 may be made of various other metals or conductors.

It is preferable that a side surface of each gate line 121 is inclined relative to a surface of the insulating substrate 110, and an inclination angle thereof is about 30° to about 80°.

A gate insulating layer 140, which is made of silicon nitride (“SiNx”), silicon oxide (“SiOx”), or so on, is formed on the gate lines 121.

A plurality of semiconductor stripes 151, which are made of hydrogenated amorphous silicon (“a-Si” is an abbreviation for amorphous silicon), polycrystalline silicon, or so on, are formed on the gate insulating layer 140. The semiconductor stripes 151 include a plurality of projections 154 which generally extend in a vertical direction and protrude toward the gate electrodes 124.

A plurality of ohmic contacts (e.g., stripes and islands) 161 and 165, respectively, are formed on the semiconductor stripes 151. The ohmic contacts 161 and 165 may be made of a material such as N+ hydrogenated amorphous silicon in which n-type impurities such as phosphorus are doped with a high concentration, or silicide. Each ohmic contact stripe 161 has a plurality of projections 163. Each projection 163 and ohmic contact island 165 are formed in pairs and disposed on a projection 154 of the semiconductor stripe 151.

Side surfaces of the semiconductor stripes 151 and the ohmic contacts 161 and 165 are also inclined relative to a surface of the insulating substrate 110, and an inclination angle thereof is about 30° to about 80°.

A plurality of data lines 171, a plurality of drain electrodes 175 and a plurality of storage capacitor conductors 177 are formed on the ohmic contacts 161 and 165 and the gate insulating layer 140.

The data lines 171 transfer a data voltage and extend substantially in a vertical direction to intersect the gate lines 121. Each data line 171 includes a plurality of source electrodes 173 which extend toward the gate electrodes 124 and bend in a ‘J’ shape, and a wide end part 179 for connecting to other layers or an external driver circuit (not shown).

One gate electrode 124, one source electrode 173, one drain electrode 175, and the projection 154 of a semiconductor stripe 151 constitute one thin film transistor (“TFT”). A channel Q of the TFT is formed in the projection 154 between the source electrode 173 and the drain electrode 175.

It is preferable that the data lines 171, the drain electrodes 175 and the storage capacitor conductors 177 are made of a refractory metal such as molybdenum, chromium, tantalum, and titanium, or their alloys, and they may have a multilayer structure including a refractory metal film (not shown) and a low resistance conductive film (not shown). The multilayer structure includes, for example, a dual-layer of a lower chromium or molybdenum (alloy) film and an upper aluminum (alloy) film, and a triple-layer of a lower molybdenum (alloy) film, a middle aluminum (alloy) film, and an upper molybdenum (alloy) film. However, the data lines 171, the drain electrodes 175 and the storage capacitor conductors 177 may be made of various other metals or conductors.

It is desirable that side surfaces of the data lines 171, the drain electrodes 175 and the storage capacitor conductors 177 are also inclined with an inclination angle of about 30° to about 80° relative to a surface of the insulating substrate 110.

The ohmic contacts 161 and 165 exist only between the lower semiconductor stripes 151 and the upper data lines 171 and drain electrodes 175, and lower a contact resistance therebetween.

The source electrodes 173 and the drain electrodes 175 have substantially the same layout as a projection 154 except at a channel part of the semiconductor stripes 151. Furthermore, the source electrodes 173 and the drain electrodes 175 have substantially the same layout as the projections 163 of the ohmic contact stripes 161 and the ohmic contact islands 165.

The reason why the source electrodes 173 and the drain electrodes 175 have the same layout is that they are manufactured by a five-mask process in a method of manufacturing according to an exemplary embodiment of the present invention. Accordingly, even if the insulating substrate 110 expands due to heat in a manufacturing process, the source electrodes 173 and the drain electrodes 175 have substantially the same layout as each of the projections 154 except for the channel part in the semiconductor stripes 151, the projections 163 of the ohmic contact stripes 161, and the ohmic contact islands 165, whereby generation of an alignment error can be prevented.

A passivation layer 180 is formed on the data lines 171, the drain electrodes 175, the storage capacitor conductors 177 and the exposed part of the semiconductor stripes 151. The passivation layer 180 is made of a non-organic insulator, an organic insulator, or so on, and may have a flat surface.

The non-organic insulator includes, for example, silicon nitride and silicon oxide. An organic insulator may have photosensitivity and preferably has a dielectric constant of about 4.0 or less. However, the passivation layer 180 may have a dual-layer structure of a lower inorganic film and an upper organic film so as not to cause damage in the exposed part of the semiconductor stripe 151 while having excellent insulating characteristics of an organic film.

A plurality of contact holes 182, 185 and 187 for exposing each of the end parts 179 of the data lines 171, the drain electrodes 175, and the storage capacitor conductors 177, respectively, are formed in the passivation layer 180. A plurality of contact holes 181 for exposing the end parts 129 of the gate lines 121 is formed in the passivation layer 180 and the gate insulating layer 140.

A plurality of pixel electrodes 190 and a plurality of contact assistants 81 and 82 are formed on the passivation layer 180. They may be made of a transparent conductive material such as ITO or IZO, or a reflective metal such as aluminum, silver, chromium, or alloys comprising at least one of the foregoing metals.

Each pixel electrode 190 is physically and electrically connected to a drain electrode 175 and a storage capacitor conductor 177 through contact holes 185 and 187, respectively. Each pixel electrode receives a data voltage from the respective drain electrode 175 and transfers the data voltage to the respective storage capacitor conductor 177.

The pixel electrode 190 to which a data voltage is applied and a common electrode (not shown) of another display panel (not shown), which receives a common voltage, generate an electric field, thereby determining a direction of liquid crystal molecules of a liquid crystal layer (not shown) between the pixel electrode 190 and the common electrode (not shown). Polarization of light passing through a liquid crystal layer (not shown) changes depending on the determined direction of the liquid crystal molecules.

As a pixel electrode 190 and the common electrode (not shown) constitute a liquid crystal capacitor, they maintain an applied voltage even after the TFT is turned off. In order to enhance voltage sustaining ability, another capacitor (hereinafter referred to as a “storage capacitor”) is connected in parallel to the liquid crystal capacitor. The storage capacitor is formed by overlapping a pixel electrode 190 and a gate line 121 (hereinafter referred to as a “previous gate line”) which is adjacent thereto. An overlapping area is increased by providing an expansion 127 at which the gate line 121 is expanded so as to increase capacitance of the storage capacitor, e.g., sustaining capacitance, and a distance between the pixel electrode 190 and the gate line 121 becomes short by providing the storage capacitor conductor 177 which is connected to the pixel electrode 190 and which is overlapped with the expansion 127 under the passivation layer 180.

When the passivation layer 180 is made of a low dielectric organic material, an aperture ratio can be increased by overlapping the pixel electrode 190 with the neighboring gate line 121 and data line 171.

The contact assistants 81 and 82 are connected to an end part 129 of the gate line 121 and an end part 179 of the data line 171 through contact holes 181 and 182, respectively. The contact assistants 81 and 82 increase adhesion between the end part 129 of the gate line 121 and the end part 179 of the data line 171 and an external apparatus, and protect them.

Now, a method of manufacturing the thin film transistor array panel shown in FIGS. 1 and 2 according to an exemplary embodiment of the present invention will be described in more detail with reference to FIGS. 1, 2 and 3A to 8B.

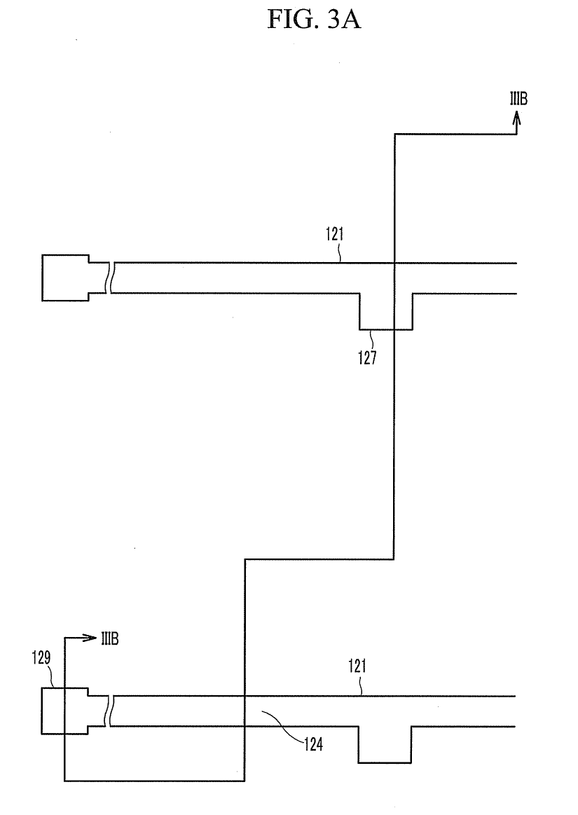

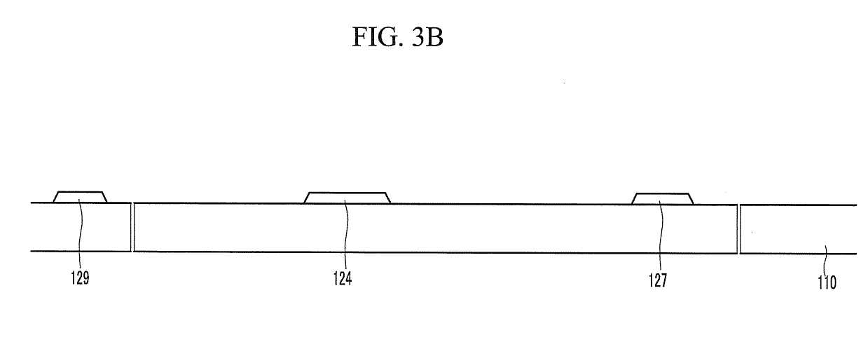

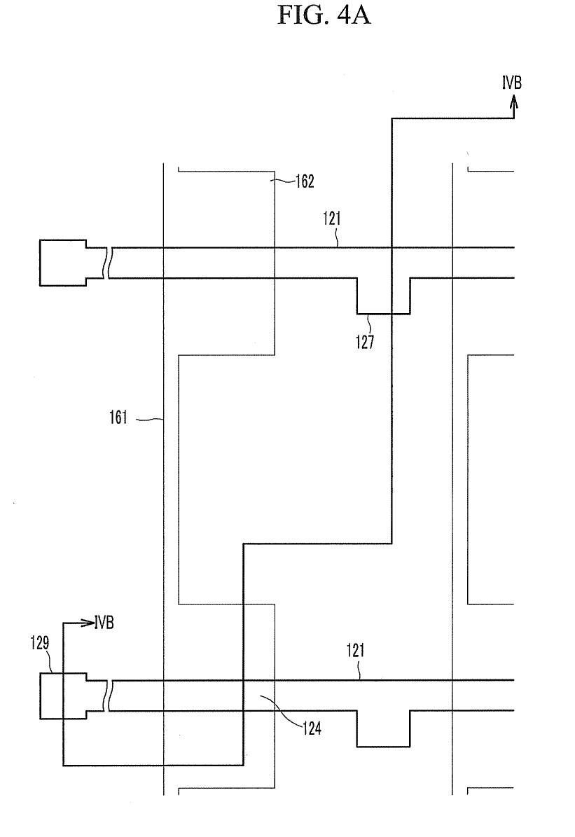

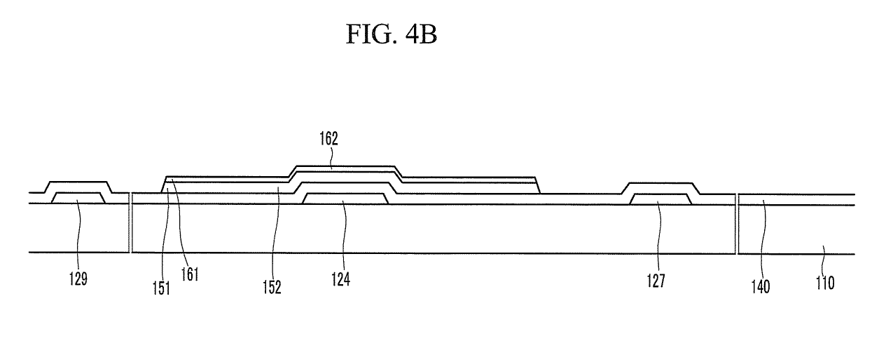

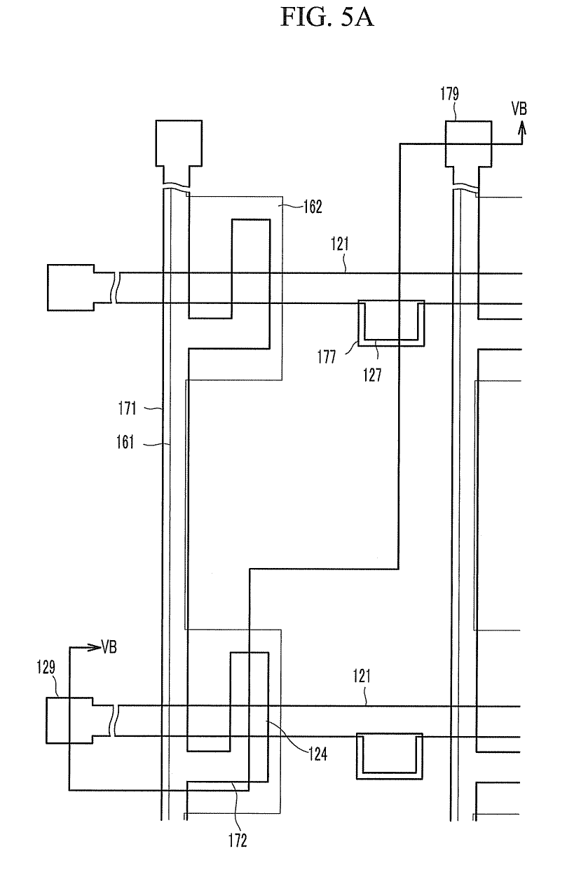

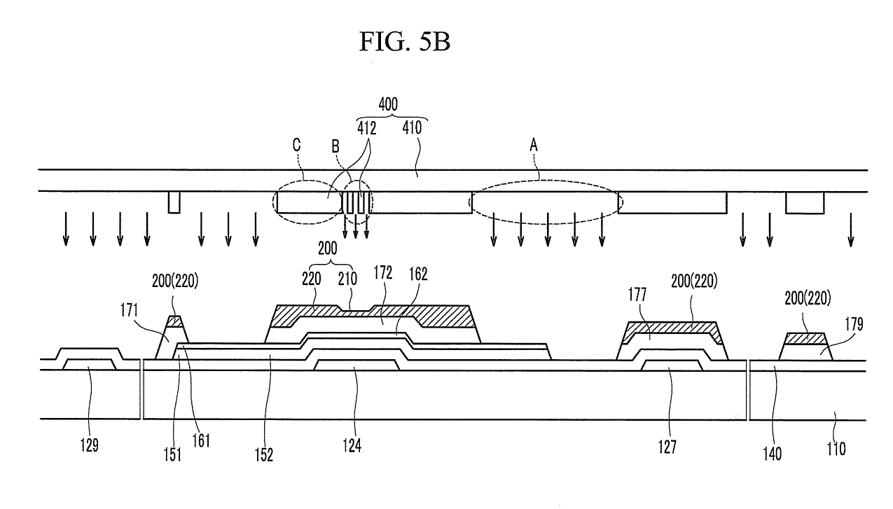

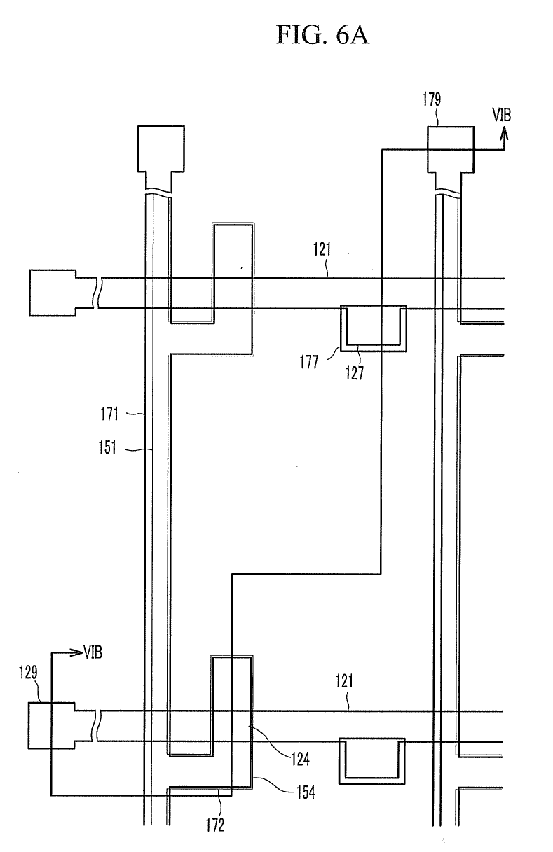

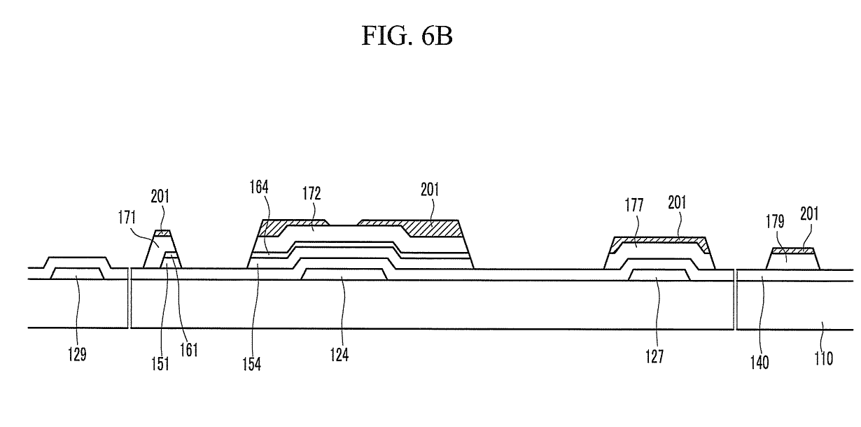

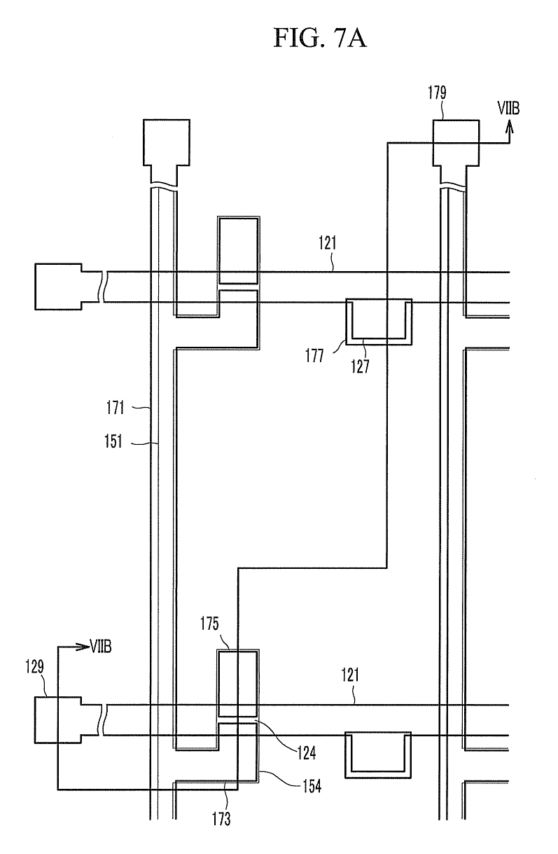

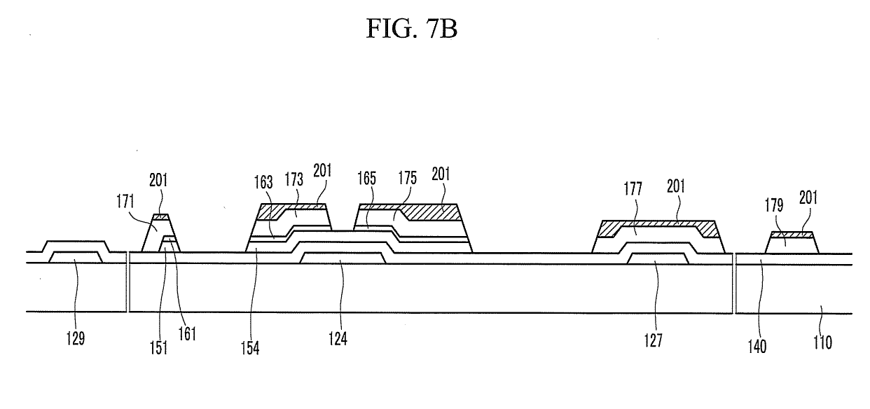

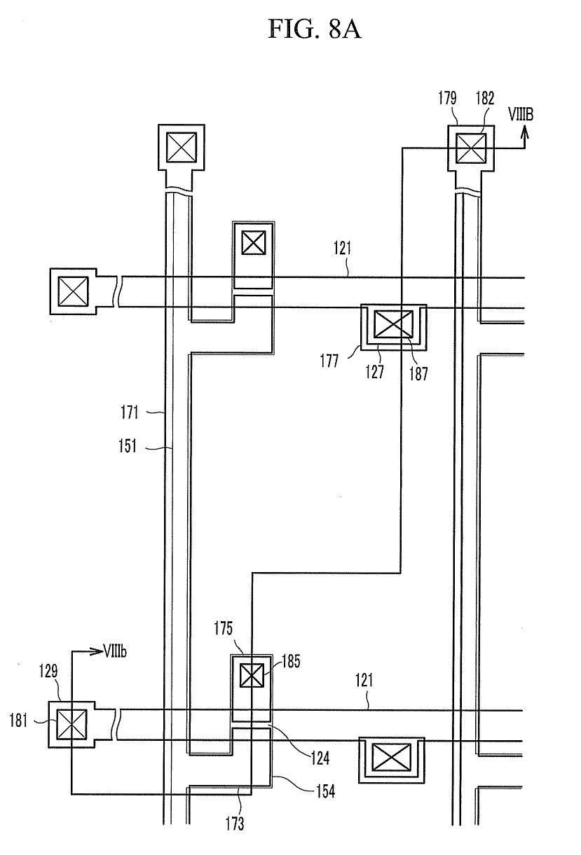

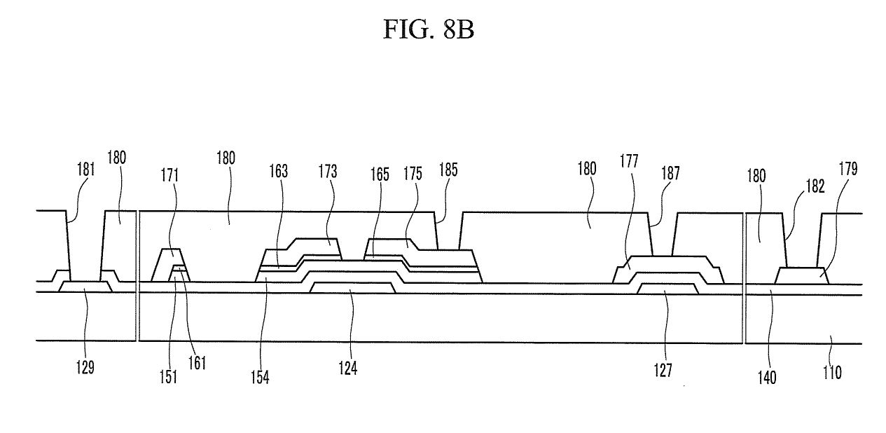

FIGS. 3A, 4A, 5A, 6A, 7A, and 8A are plan view layouts sequentially illustrating the thin film transistor array panel in an intermediate step of a method of manufacturing the thin film transistor array panel shown in FIGS. 1 and 2 according to an exemplary embodiment of the present invention. FIG. 3B is a cross-sectional view of the thin film transistor array panel taken along line IIIb-IIIb of FIG. 3A. FIG. 4B is a cross-sectional view of the thin film transistor array panel taken along line IVb-IVb of FIG. 4A. FIG. 5B is a cross-sectional view of the thin film transistor array panel taken along line Vb-Vb of FIG. 5A. FIG. 6B is a cross-sectional view of the thin film transistor array panel taken along line VIb-VIb of FIG. 6A. FIG. 7B is a cross-sectional view of the thin film transistor array panel taken along line VIIb-VIIb of FIG. 7A, and FIG. 8B is a cross-sectional view of the thin film transistor array panel taken along line VIIIb-VIIIb of FIG. 8A.

First, a conductive film consisting of an aluminum metal such as aluminum and an aluminum alloy, a silver metal such as silver and a silver alloy, a copper metal such as copper and a copper alloy, a molybdenum metal such as molybdenum and a molybdenum alloy, chromium, titanium, tantalum, etc., is formed on the insulating substrate 110 with a method such as sputtering, for example, but is not limited thereto.

Thereafter, as shown in FIGS. 3A and 3B, a plurality of gate lines 121 including a plurality of gate electrodes 124, a plurality of expansions 127 which protrude in the downward direction in FIG. 3A, and an end part 129 are formed by patterning a conductive film through a photolithography process using a first mask (not shown).

Next, a gate insulating layer 140, a hydrogenated amorphous silicon film, which is a semiconductor material layer, and an N+ doped amorphous silicon film, which is an ohmic contact material layer, are sequentially stacked with a method including low temperature chemical vapor deposition (“LTCVD”) or plasma enhanced chemical vapor deposition (“PECVD”), for example, so as to cover the gate lines 121.

Thereafter, as shown in FIGS. 4A and 4B, a first semiconductor layer pattern 152 and a first ohmic contact pattern 162 for fully covering the gate electrode 124 and an area surrounding of the gate electrode 124 are formed by patterning a hydrogenated amorphous silicon film, which is a semiconductor material layer, and an N+ doped amorphous silicon film, which is an ohmic contact material layer, through a photolithography process using a second mask (not shown).

Next, a conductive film consisting of chromium metals or molybdenum metals and refractory metals such as tantalum and titanium is stacked with a method including sputtering, for example, on the gate insulating layer 140 and the first ohmic contact pattern 162.

Thereafter, as shown in FIGS. 5A and 5B, a conductive film pattern 172 and a data line 171 are respectively formed on a partial area of the first ohmic contact pattern 162 and on the gate insulating layer 140 by patterning a conductive film with a photolithography process using a third mask 400.

Specifically, after a photoresist is coated on the conductive film, the photoresist is exposed using the third mask 400.

The third mask 400 used for exposure includes a transparent substrate 410 and a non-transparent film 412 formed thereon. The non-transparent film 412 may be made of chromium or chromium oxide, which are materials through which light cannot transmit during exposure, or it may be formed in a dual-layer made of each of chromium and chromium oxide.

The third mask 400 includes three areas of a part A consisting of only the transparent substrate 410, a part B consisting of the transparent substrate 410 and the non-transparent film 412 formed with a plurality of slit shapes, and a part C consisting of the transparent substrate 410 and the non-transparent film 412 is formed in a fixed thickness.

When light is irradiated to the photoresist with the third mask 400 interposed therebetween, as indicated with arrows having a different length in a lower part of the third mask 400 of FIG. 5B, the intensity of light passing through the third mask 400 is different in each area. That is, as part A includes only the transparent substrate 410 almost all light passes, so exposure intensity is very large in the photoresist corresponding to part A. In part B, as light diffracts when it passes through the transparent substrate 410 and the non-transparent film 412 having a slit shape, exposure intensity in a part of the photoresist corresponding to part B is relatively weaker than that in the part of the photoresist corresponding to part A. Furthermore, in part C, as light does not pass through the third mask 400, exposure is not performed in a lower part of the photoresist corresponding to part C.

As exposure intensity of the photoresist is different in each part of the photoresist, as shown in FIG. 5B, the photoresist is entirely removed in a lower part corresponding to part A when the photoresist is developed using a developing solution after exposure. Furthermore, a part 210 corresponding to part B among the photoresist patterns 200 has a smaller thickness than a part 220 corresponding to part C.

When a conductive film which is exposed in the lower part is etched using the photoresist pattern 200 as an etching mask, the data line 171 including the end part 179 and a plurality of conductive film patterns 172 which are bent in a J shape is formed in a partial area of the first ohmic contact pattern 162 and a storage capacitor conductor 177 is formed on the expansion 127.

Thereafter, as shown in FIGS. 6A and 6B, the first semiconductor layer pattern 152 and the first ohmic contact pattern 162 which are exposed by deviating from the conductive film pattern 172 are removed by sequentially etching using the photoresist pattern 200 as an etching mask. t as the conductive film pattern 172, are formed. Accordingly, a projection 154, which is a part of the semiconductor stripe 151, and the second ohmic contact pattern 164 having the same layout as the conductive film pattern 172, are formed. As the entire thickness of the photoresist pattern 200 decreases in an etching process, the part 210 corresponding to the part B is removed. Accordingly, the photoresist pattern 201, in which a part of the lower conductive film pattern 172 is exposed, is formed. When the part 210 corresponding to part B remains without being removed, the conductive film pattern 172 corresponding to part B is exposed by ashing the photoresist pattern 201.

Thereafter, as shown in FIGS. 7A and 7B, a drain electrode 175 which is separated from the source electrode 173 and the data line 171 including the source electrode 173 are formed by patterning the conductive film pattern 172 which is exposed by the photoresist pattern 201.

Thereafter, an ohmic contact island 165 and an ohmic contact stripe 161 including the projection 163 are formed by patterning a part of the second ohmic contact pattern 164 exposed between the separated source electrode 173 and drain electrode 175 through etching.

Thereafter, a passivation layer 180 is formed by removing the photoresist pattern 201 and then forming an organic material having excellent planarization characteristics and photosensitivity, a low dielectric insulating material such as a-Si:C:O and a-Si:O:F, which are formed with PECVD, or silicon nitride (“SiNx”), which is an inorganic material with a single layer or a plurality of layers.

Next, as shown in FIGS. 8A and 8B, a plurality of contact holes 181, 185, 187, and 182 are formed through patterning the passivation layer 180 with a photolithography process using a fourth mask (not shown) after coating photoresist (not shown) on the passivation layer 180.

Next, a manufacturing process of the thin film transistor array panel shown in FIGS. 1 and 2 is completed by stacking ITO or IZO on the passivation layer 180 by sputtering and forming a plurality of pixel electrodes 190 and a plurality of contact assistants 81 and 82 through patterning ITO or IZO with a photolithography process using a fifth mask (not shown).

In a method of manufacturing of a thin film transistor array panel according to an exemplary embodiment of the present invention, the first semiconductor layer pattern 152 and the first ohmic contact pattern 162 having a sufficient area are first formed under a part in which the source electrode 173 and the drain electrode 175 are formed. Before being divided into the source electrode 173 and the drain electrode 175, the conductive pattern 172 and the photosensitive film pattern 200 which is formed thereon form the projection 154 of the semiconductor stripe 151 and the second ohmic contact pattern 164 is used as an etching mask for self-alignment. Thereafter, the source electrode 173 and the drain electrode 175 which are separated from each other are formed by patterning the conductive film pattern 172 using the photoresist pattern 201, and the projection 163 of the ohmic contact stripe 161 and the ohmic contact island 165 are formed by patterning the second ohmic contact pattern 164 using the source electrode 173, the drain electrode 175 and the photoresist pattern 201 as an etching mask for self-alignment.

Therefore, when the thin film transistor array panel is manufactured through a fifth mask process, the source electrode 173 and the drain electrode 175 can be formed having substantially the same layout as each of the projections 154 except for a channel part in the semiconductor stripe 151, the projection 165 of the ohmic contact stripe 161, and the ohmic contact island 163 even if the insulating substrate 110 is expanded due to heat from a manufacturing process. Therefore, generation of erroneous alignment can be prevented between the projection 154 of the semiconductor stripe 151 and the source electrode 173 and the drain electrode 175.

As described above, according to the present invention, even if an insulating substrate is expanded by heat, erroneous alignment is prevented between the projection of the semiconductor layer and the source electrode and the drain electrode, so that a thin film transistor array panel having excellent manufacturing efficiency and performance and a method of manufacturing the same are obtained.

While the present invention has been described in connection with what is presently considered to be practical exemplary embodiments, it is to be understood that the present invention is not limited to the disclosed exemplary embodiments, but, on the contrary, is intended to cover various modifications and equivalent arrangements included within the spirit and scope of the appended claims.

What is claimed is:

1. A thin film transistor array panel comprising:
a gate electrode formed on an insulating substrate;
a gate insulating layer, a semiconductor layer pattern and an ohmic contact sequentially formed on the gate electrode;
a source electrode and a drain electrode formed on the ohmic contact;
a data line connected to the source electrode;
and
a pixel electrode connected to the drain electrode,
wherein the semiconductor layer pattern comprises a part having substantially a same layout as that of the source electrode and the drain electrode
and wherein at least a portion of the data line is formed directly on the gate insulating layer.

2. The thin film transistor array panel of claim 1, wherein the insulating substrate is flexible.

3. The thin film transistor array panel of claim 2, wherein the insulating substrate is made of plastic.

4. The thin film transistor array panel of claim 1, wherein a remaining part except a channel part in the semiconductor layer pattern comprises a part having substantially a same layout as that of the source electrode and the drain electrode.

5. The thin film transistor array panel of claim 1, wherein the ohmic contact pattern comprises a part having substantially a same layout as that of the source electrode and the drain electrode.

6. A method of manufacturing a thin film transistor array panel, comprising:
forming a gate electrode on an insulating substrate;
sequentially forming a gate insulating layer, a semiconductor material layer and an ohmic contact material layer on the gate electrode;
forming a first semiconductor layer pattern and a first ohmic contact pattern for covering the gate electrode and an area surrounding of the gate electrode by patterning the semiconductor material layer and the ohmic contact material layer;
forming a conductive film on the gate insulating layer and the first ohmic contact pattern;
forming a conductive film pattern on a partial area of the first ohmic contact pattern and a data line on the gate insulating layer by patterning the conductive film;
forming a second ohmic contact pattern and a second semiconductor layer pattern by sequentially etching the first ohmic contact pattern and the first semiconductor layer pattern exposed by deviating from the conductive film pattern;
forming a source electrode and a drain electrode which are separated from each other by patterning the conductive film pattern;
forming an ohmic contact by etching the second ohmic contact pattern exposed between the separated source electrode and drain electrode; and
forming a pixel electrode connected to the drain electrode.

7. The method of claim 6, wherein the forming of the conductive film pattern comprises:
forming a photoresist on the conductive film;
exposing the photoresist using an exposure mask comprising a first part consisting of only a transparent substrate, a second part consisting of a non-transparent film having a plurality of slit shapes on the transparent substrate, and a third part consisting of a non-transparent film formed in a predetermined thickness on the transparent substrate;
forming a photoresist pattern in which a fourth part of the developed photoresist corresponding to the second part has a smaller thickness than a fifth part of the developed photoresist corresponding to the third part by developing the exposed photoresist; and
etching a conductive film using the photoresist pattern as an etching mask.

8. The method of claim 7, wherein, in the forming of the second ohmic contact pattern and the second semiconductor layer pattern,
the fifth part of the photoresist pattern is removed through etching.

9. The method of claim 8, wherein the forming of the source electrode and the drain electrode comprises etching the conductive film pattern using the photoresist pattern in which the fifth part is removed as an etching mask.

10. The method of claim 8, wherein the forming of the ohmic contact comprises etching the second ohmic contact pattern using the photoresist pattern in which the fifth part is removed as an etching mask.

11. The method of claim 6, wherein the insulating substrate is flexible.

12. The method of claim 11, wherein the insulating substrate is made of plastic.

13. The method of claim 6, wherein in the forming of the ohmic contact,
the ohmic contact comprises a part having substantially a same layout as that of the source electrode and the drain electrode.

14. The method of claim 6, wherein, in the forming of the second semiconductor layer pattern,
the second semiconductor layer pattern comprises a part having substantially a same layout as that of the source electrode and the drain electrode.

15. The method of claim 14, wherein, in the forming of the second semiconductor layer pattern,
a remaining part except a channel part in the second semiconductor layer pattern has substantially a same layout as that of the source electrode and the drain electrode.
